(19) United States
(12) Patent Application Publication
(10) Pub. No.: US 2026/0113041 A1
(43) Pub. Date: Apr. 23, 2026

(54) Voltage control circuit and voltage generation device

(71) Applicant: SITRONIX TECHNOLOGY CORP., Hsinchu County (TW)

(72) Inventors: Chih-Hung Huang, Hsinchu County (TW); Li-Yu Huang, Hsinchu County (TW)

(21) Appl. No.: 19/363,155

(22) Filed: Oct. 20, 2025

Related U.S. Application Data
(60) Provisional application No. 63/708,785, filed on Oct. 18, 2024.

(51) Int. Cl. H03L 5/00; G09G 3/20; H02M 3/07

(52) U.S. Cl. CPC H03L 5/00; G09G 3/2092; G09G 2330/028; H02M 3/07

(57) ABSTRACT

The present application discloses a voltage control circuit and a voltage generation device. The voltage control circuit includes a first voltage terminal, a second voltage terminal and a voltage adjustment unit. The first voltage terminal provides a first voltage, the first second terminal provides a second voltage, and the first and second voltage terminals are coupled to a capacitor during a charging phase so that the capacitor receives the first and second voltages. The voltage adjustment unit adjusts the voltage of the capacitor during a pushing phase. The voltage control circuit generates multiples of the first voltage or multiples of the second voltage via the capacitor during the pushing phase. The voltage generation device includes a first voltage generation circuit, a second voltage generation circuit, a capacitor, and the voltage control circuit.

### FIELD OF THE INVENTION

The present application relates to a voltage control circuit and a voltage generation device, and in more particular to a voltage control circuit and a voltage generation device used for a display panel.

### BACKGROUND OF THE INVENTION

A voltage output device used for a display panel needs to provide a voltage required for driving the display elements on the display panel, such as providing plural multiples of the system voltage. When the voltage output device provides the plural multiples of the system voltage, it may exceed the process withstand Voltage limitation of the internal electronic components of the voltage output device, causing damage or fault.

Please refer to FIG. 1, which is a schematic diagram of a voltage generation circuit according to the prior art. The voltage generation circuit 1 includes charge pump circuits P1, P2, and P3, each of the charge pump circuits P1, P2, and P3 includes capacitors C1, C2, and C3. Based on the voltages required for operating the display panel, the voltage generation circuit 1 generates different voltages, such as low, medium, and high voltages, to an external storage capacitor CS by connecting the capacitors C1, C2, and C3 within the charge pump circuits P1, P2, and P3 in series. For example, generating a high voltage required for being capable of driving the display elements on the display panel. In this embodiment, for example, each of the capacitors C1, C2, and C3 may store a double of system voltage VDD. By connecting the capacitors C1, C2, and C3 in series, six multiples of the system voltage VDD (6VDD) may be provided to the storage capacitor CS for driving the display elements and display an image. However, generating a high voltage by connecting a plurality of capacitors in series not only significantly occupies internal circuit space but also decreases the equivalent capacitance value, resulting in a quantity of charges stored in the capacitors to be smaller correspondingly. Furthermore, when the generated high voltage exceeds the process withstand voltage of the internal elements, it may cause damage or malfunction for the internal circuit elements.

According to the above, the present application provides a voltage control circuit and a voltage generation circuit to overcome the various technical problems mentioned above.

### SUMMARY OF THE INVENTION

An objective of the present application is to provide a voltage control circuit, comprising a first voltage terminal, a second voltage terminal, and a voltage adjustment unit. During the charging phase, a capacitor is coupled to the first and second voltage terminals, allowing the capacitor to receive the first and second voltages. The capacitor is disposed outside the voltage control circuit. During the pushing phase, the voltage control circuit generates a plurality of times the first voltage or a plurality of times the second voltage through the capacitor.

An objective of the present application is to provide a voltage control circuit, comprising a first voltage terminal, a second voltage terminal, and a voltage adjustment unit. During the charging and pushing phases, the voltage control circuit outputs a positive or negative voltage exceeding the process voltage of the internal electronic components via a capacitor disposed outside the voltage control circuit, without causing damage or malfunction to the internal electronic components, meeting withstand voltage specifications of the electronic components, and achieving the technical effect of outputting the positive or negative voltage required at different times.

An objective of the present application is to provide a voltage generation device, comprising a first voltage generating circuit, a second voltage generating circuit, a capacitor, and a voltage control circuit. A first voltage generating circuit provides a first voltage, a second voltage generating circuit provides a second voltage, a capacitor receives the first and second voltages during the charging phase, and a voltage control circuit adjusts the voltage of the capacitor during the pushing phase. The voltage control circuit generates a plurality of times the first voltage or a plurality of times the second voltage through the capacitor during the pushing phase. The capacitor is disposed externally in the voltage generating device.

An objective of the present application is to provide a voltage generating device comprising a first voltage generating circuit, a second voltage generating circuit, a capacitor, and a voltage control circuit. This device outputs a positive or negative voltage exceeding the process voltage of the internal electronic components via a capacitor disposed externally, without causing damage or malfunction to the internal electronic components, meeting withstand voltage specifications of the electronic components, and achieving the technical effect of outputting the positive or negative voltage required at different times.

### BRIEF DESCRIPTION OF DRAWINGS

FIG. 1: A schematic diagram of a voltage generation device according to the prior art.

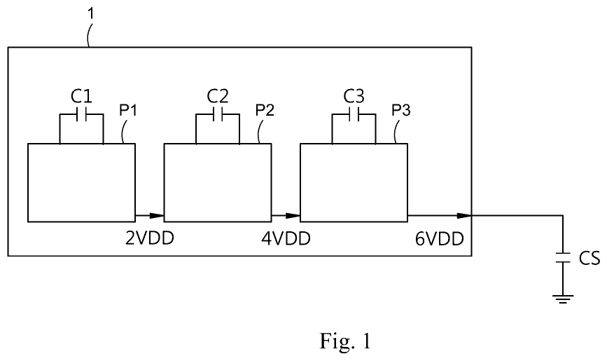

FIG. 2: A block diagram of a voltage generation device according to the present application.

FIG. 3: An operational schematic diagram of a voltage control circuit in a charging phase according to an embodiment of the present application.

FIG. 4: An operational schematic diagram of the voltage control circuit in a pushing phase according to an embodiment of the present application.

FIG. 5: An operational schematic diagram of the voltage control circuit in the charging phase according to another embodiment of the present application.

FIG. 6: An operational schematic diagram of the voltage control circuit in the pushing phase according to another embodiment of the present application.

### DETAILED DESCRIPTION OF THE INVENTION

In order to provide the esteemed reviewers with a further understanding and recognition of the features and effects achieved by the present application, a preferred embodiment is presented along with a detailed description as follows:

Certain terms used in the specification and claims refer to specific components; however, those skilled in the art should understand that manufacturers may use different terms to refer to the same component. Furthermore, the specification and claims do not distinguish components based on the difference in terms, but rather on the technical differences of the components. The term “comprising” mentioned throughout the specification and claims is an open-ended term and should be interpreted as “including but not limited to.” Moreover, the term “coupling” here includes any direct and indirect means of connection. Therefore, if the text describes a first device coupled to a second device, it implies that the first device may be directly connected to the second device, or indirectly connected through other devices or means of connection.

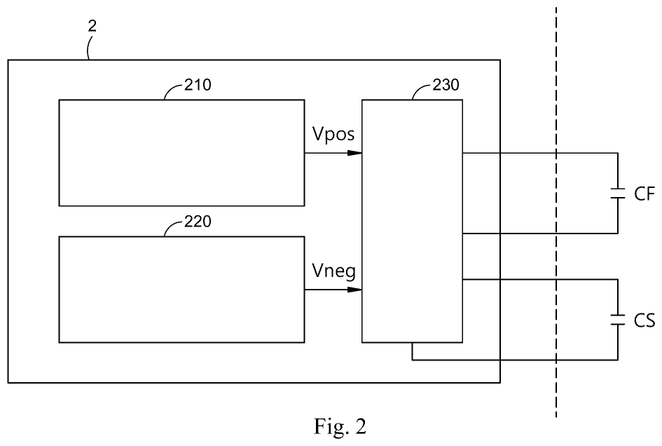

Please refer to FIG. 2, which is a block diagram of the voltage generation device according to the present application. The voltage generation device 2 according to the present application is used to provide voltage to a display panel for supplying a voltage required for operating the display panel, such as providing a high voltage to the display elements on the display panel to drive the display elements for displaying images. For example, the display panel is a Super Twisted Nematic (STN) display panel, a LTPS (Low Temperature Polysilicon) display panel, other LCD (Liquid Crystal Display) display panel, or an OLED (Organic Light Emitting Diode) display panel. The voltage generation device 2 includes a first voltage generation circuit 210, a second voltage generating circuit 220, and a voltage control circuit 230. The first voltage generating circuit 210 provides a first voltage Vpos, the second voltage generating circuit 220 provides a second voltage Vneg, and the voltage control circuit 230 receives the first voltage Vpos and the second voltage Vneg. A capacitor CF and a storage capacitor CS are coupled to the voltage control circuit 230. The capacitor CF and the storage capacitor CS are disposed outside the voltage control circuit 230, shown as dashed lines in FIG. 2 to be indicative of being disposed outside. In this embodiment, the capacitor CF is a flying capacitor, providing functions for the voltage generation device 2, such as voltage boosting, energy storage, and energy transfer. The first voltage generating circuit 210 and the second voltage generating circuit 220 are charge pump circuits.

In this embodiment, the first voltage Vpos provided by the first voltage generating circuit 210 is a positive voltage, and the second voltage Vneg provided by the second voltage generating circuit 220 is a negative voltage. For example, the first voltage Vpos is double of the system positive voltage. The first voltage generating circuit 210 receives the system voltage and boosts it to double of the positive voltage through an internal capacitor to provide the first voltage Vpos. For example, the second voltage Vneg is double of the system negative voltage. The first voltage generating circuit 210 receives the system voltage and converts the system voltage to double of the negative voltage through the internal capacitor to provide the second voltage Vneg.

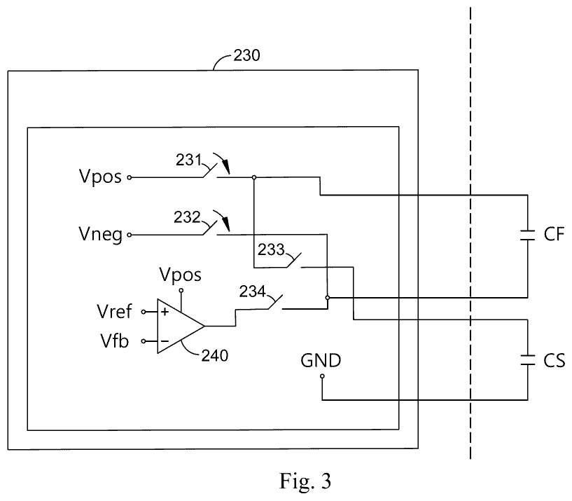

Please refer to FIG. 3, which is an operational schematic diagram of the voltage control circuit during the charging phase according to an embodiment of the present application. The voltage control circuit 230 includes a first voltage terminal, a second voltage terminal, a first switching circuit 231, a second switching circuit 232, a third switching circuit 233, a fourth switching circuit 234, and a voltage adjustment unit 240. The capacitor CF and the storage capacitor CS each have a first terminal and a second terminal. The first switching circuit 231 is coupled to the first voltage terminal and the first terminal of the capacitor CF, and the second switching circuit 232 is coupled to the second voltage terminal and the second terminal of the capacitor CF. During the charging phase, the first switching circuit 231 and the second switching circuit 232 are turned on, and the third switching circuit 233 and the fourth switching circuit 234 are turned off. The capacitor CF receives the voltage Vpos from the first voltage terminal through the turn-on of the first switching circuit 231, and the capacitor CF receives the voltage Vneg from the second voltage terminal through the turn-on of the second switching circuit 232. In this embodiment, the voltage Vpos is double of the positive system voltage, and the voltage Vneg is double of the negative system voltage, therefore, during the charging phase, the capacitor CF stores quadruple of the system voltage.

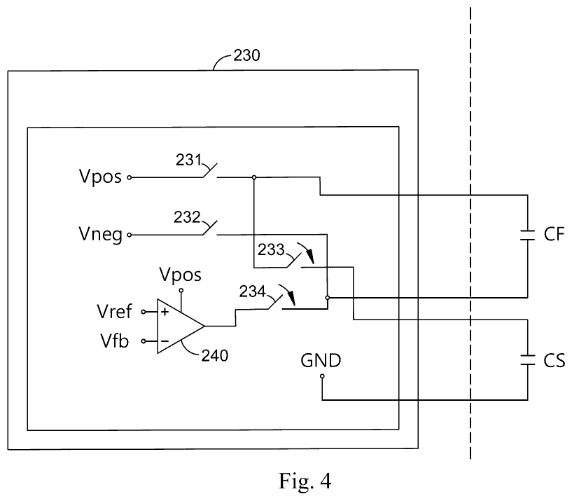

Please refer to FIG. 4, which is an operational schematic diagram of the voltage control circuit in the pushing phase according to an embodiment of the present application. The third switching circuit 233 is coupled to the first terminal of capacitor CF and the first terminal of the storage capacitor CS, and the fourth switching circuit 234 is coupled to the second terminal of the capacitor CF and the voltage adjustment unit 240. In a pushing phase, the third switching circuit 233 and the fourth switching circuit 234 are turned on, and the first switching circuit 231 and the second switching circuit 232 are turned off. The first terminal of the storage capacitor CS receives the voltage of the first terminal of the capacitor CF through the turn-on of the third switching circuit 233, and the voltage adjustment unit 240 receives the voltage of the capacitor CF through the turn-on of the fourth switching circuit 234. In the pushing phase, since the first terminal of the storage capacitor CS receives double of the positive system voltage from the first terminal of capacitor CF, plus quadruple of the system voltage stored by capacitor CF during the charging phase, the voltage at the first terminal of storage capacitor CS becomes six times the positive system voltage in the pushing phase, allowing the storage capacitor CS to store six times the positive system voltage to provide the high voltage required for operating the display panel. Through the aforementioned charging and pushing phases, the voltage control circuit 230 may output a high voltage exceeding the process voltage of the internal electronic components via the capacitor CF disposed externally, without damaging or malfunctioning the internal electronic components, thus meeting withstand voltage specifications of the electronic components.

The voltage adjustment unit 240 includes a first input terminal, a second input terminal, and an output terminal. During the pushing phase, the first input terminal of the voltage adjustment unit 240 receives a reference voltage Vref, the second input terminal of the voltage adjustment unit 240 receives a feedback voltage Vfb, and the output terminal of the voltage adjustment unit 240 is coupled to the second terminal of the capacitor CF. According to actual output requirements, the voltage control circuit 230 adjusts the voltage of the capacitor CF through the voltage adjustment unit 240. The voltage control circuit 230 sets the reference voltage Vref and the feedback voltage Vfb according to the output voltage requirements. In an embodiment, the voltage of the capacitor CF is required to 15V, the reference voltage is set to 1.5V, and the feedback voltage Vfb is a portion of the voltage of the capacitor CF, for example, one-tenth of the voltage of the capacitor CF, which may also be set to other proportions depending on the actual situation, such as half of the voltage of the capacitor CF. In this embodiment, the portion of the voltage of the capacitor CF is a portion of the voltage at the second terminal of the capacitor CF. After receiving the reference voltage Vref and the feedback voltage Vfb, the voltage adjustment unit 240 outputs a voltage to the capacitor CF based on the voltage difference between both. For example, when the reference voltage Vref is greater than the feedback voltage Vfb, the output terminal of the voltage adjustment unit 240 outputs a positive voltage to the capacitor CF, increasing the voltage of the capacitor CF and thus increasing the voltage of the feedback voltage Vfb. Reversely, when the reference voltage Vref is less than the feedback voltage Vfb, the output terminal of the voltage adjustment unit 240 outputs a negative voltage to the capacitor CF, decreasing the voltage of the capacitor CF and thus decreasing the voltage of the feedback voltage Vfb. This operation of the voltage adjustment unit 240 continues until the feedback voltage Vfb equals the reference voltage Vref. When the feedback voltage Vfb equals the reference voltage Vref, in the above embodiment, the feedback voltage Vfb is 1.5V, indicative of the voltage of the capacitor CF to 15V, which is the required voltage. In this embodiment, the voltage adjustment unit 240 is an operational amplifier (OPA).

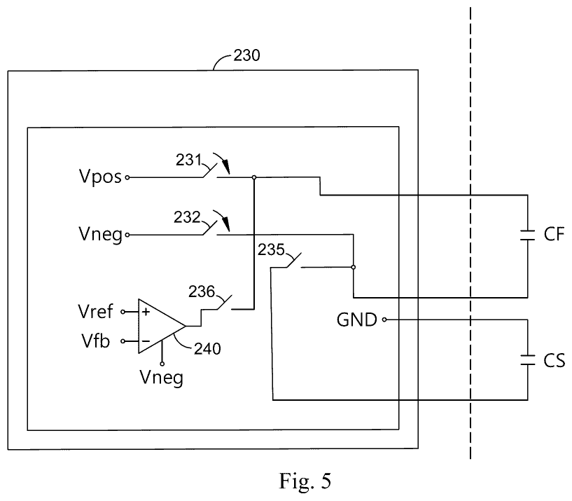

Please refer to FIG. 5, which is an operational schematic diagram of the voltage control circuit during the charging phase according to another embodiment of the present application. The voltage control circuit 230 includes a first voltage terminal, a second voltage terminal, a first switching circuit 231, a second switching circuit 232, a fifth switching circuit 235, a sixth switching circuit 236, and a voltage adjustment unit 240. The capacitor CF and the storage capacitor CS include a first terminal and a second terminal respectively. The first switching circuit 231 is coupled to the first voltage terminal and the first terminal of the capacitor CF, and the second switching circuit 232 is coupled to the second voltage terminal and the second terminal of the capacitor CF. During the charging phase, the first switching circuit 231 and the second switching circuit 232 are turned on, and the fifth switching circuit 235 and the sixth switching circuit 236 are turned off. The capacitor CF receives the first voltage Vpos of the first voltage terminal through the turn-on of the first switching circuit 231, and the capacitor CF receives the second voltage Vneg of the second voltage terminal through the turn-on of the second switching circuit 232. In this embodiment, the first voltage Vpos is double of the positive system voltage, and second voltage Vneg is double of the negative system voltage. Therefore, during the charging phase, capacitor CF stores quadruple of the system voltage.

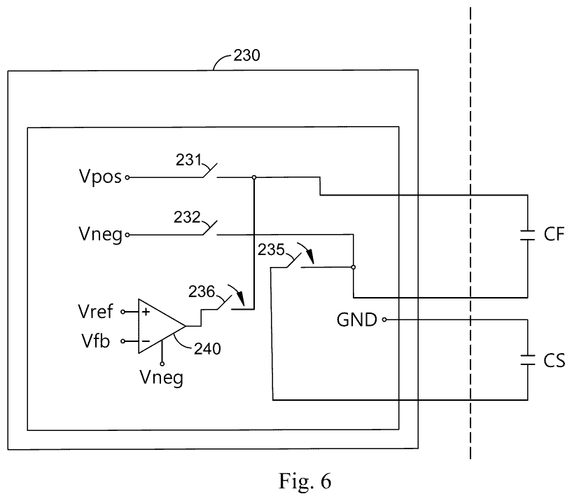

Please refer to FIG. 6, which is an operational schematic diagram of the voltage control circuit in the pushing phase according to another embodiment of the present application. The fifth switching circuit 233 is coupled to the second terminal of the capacitor CF and the second terminal of the storage capacitor CS, and the sixth switching circuit 236 is coupled to the first terminal of the capacitor CF and the voltage adjustment unit 240. During the pushing phase, the fifth switching circuit 235 and the sixth switching circuit 236 are turned on, and the first switching circuit 231 and the second switching circuit 232 are turned off. The second terminal of the storage capacitor CS receives the voltage at the second terminal of the capacitor CF through the turn-on of the fifth switching circuit 235, and the voltage adjustment unit 240 receives the voltage of the capacitor CF through the turn-on of the sixth switching circuit 236. During the pushing phase, since the second terminal of the storage capacitor CS receives double of the negative system voltage from the second terminal of the capacitor CF, plus quadruple of the system voltage stored in the capacitor CF during the charging phase, the voltage at the second terminal of the storage capacitor CS becomes six times the system negative voltage during the pushing phase, allowing the storage capacitor CS to store six times the system negative voltage, providing the negative voltage required for operating the display panel. Through the aforementioned charging and pushing phases, the voltage control circuit 230 outputs a negative voltage exceeding the process voltage of the internal electronic components via the capacitor CF disposed externally, without causing damage or malfunction to the internal electronic components, thus meeting withstand voltage specifications of the electronic components.

In an embodiment, the system voltage is 3V. The voltage generation device 2 generates the high voltage required for operating the display panel, such as generating six times the system positive and negative voltages, 18V and −18V, providing the high voltage to allow the display elements on the display panel to display normally.

Furthermore, since the capacitor CF is an external capacitor disposed externally to the voltage generation device 2, it not only saves internal circuit space but also allows for the selection of a larger capacitance value to store more electric charges. In other words, the capacitance of the capacitor CF may be much larger than the internal capacitance of the voltage generation device 2. For example, if the internal capacitance of the voltage generation device 2 is 1 nF, then the capacitor CF may be selected as 1 uF, causing a difference of 1000 times between both. Moreover, the high voltage generated by the voltage generation device 2 is generated by the capacitor CF disposed externally and will not affect the internal electronic components of the voltage generation device 2, allowing the voltage generation device 2 to operate at voltages meeting the process withstand voltages, such as double of the system voltage. High voltages exceeding the process withstand voltage are operated through the capacitor CF disposed externally, such as six times the system voltage.

Through the voltage control circuit and voltage generation device of the present application, the capacitor disposed externally outputs a high voltage exceeding the process voltage of the internal electronic components without causing damage or malfunction to the internal electronic components, thus meeting withstand voltage specifications of the electronic components. Compared to technologies of prior art, the capacitors inside the voltage generation device connected in serious connection generate high voltage, the capacitor according to the present application is disposed outside the voltage generation device, which greatly saves internal circuit space, and also improves the selectivity of the capacitor. The capacitance value may be selected to be much larger than the capacitance inside the voltage generation device according to actual needs, thereby improving the practicality and safety of the voltage generation device.

Therefore, the present application is indeed novel, inventive and industrially applicable, and should undoubtedly meet the requirements for patent application under the Patent Law. Therefore, the applicant hereby files an invention patent application in accordance with the Patent law, and earnestly pray that the Bureau will grant the patent as soon as possible.

The above descriptions are merely preferred embodiments of the present application, and all equivalent variations and modifications within the scope of the patent application for the present application are intended to be within the scope of the present application.

1. A voltage control circuit comprising:
a first voltage terminal, providing a first voltage;
a second voltage terminal, providing a second voltage, wherein the first voltage terminal and the second voltage terminal are coupled to a capacitor during a charging phase so that the capacitor receives the first voltage and the second voltage; and
a voltage adjustment unit, adjusting a voltage of the capacitor during a pushing phase, wherein the voltage control circuit generates multiples of the first voltage or multiples of the second voltage through the capacitor during the pushing phase.

2. The voltage control circuit of claim 1, wherein the voltage adjustment unit receives a portion of the voltage of the capacitor and a reference voltage during the pushing phase, when the portion of the voltage of the capacitor is different from the reference voltage, the voltage adjustment unit adjusts the voltage of the capacitor.

3. The voltage control circuit of claim 1, wherein the capacitor is an external capacitor, disposed outside the voltage control circuit, and the capacitor comprises a first terminal and a second terminal.

4. The voltage control circuit of claim 3, further comprising:
a first switching circuit, coupled to the first terminal of the capacitor, the first terminal of the capacitor receiving the first voltage through the first switching circuit during the charging phase; and
a second switching circuit, coupled to the second terminal of the capacitor, the second terminal of the capacitor receiving the second voltage through the second switching circuit during the charging phase.

5. The voltage control circuit of claim 3, further comprising:
a third switching circuit, coupled to the first terminal of the capacitor, wherein the voltage control circuit outputs the first voltage or multiples of the first voltage through the third switching circuit during the pushing phase; and
a fourth switching circuit, coupled to the voltage adjustment unit, wherein the voltage adjustment unit receives the voltage of the capacitor through the fourth switching circuit during the pushing phase.

6. The voltage control circuit of claim 3, further comprising:
a fifth switching circuit, coupled to the second terminal of the capacitor, wherein the voltage control circuit outputs the second voltage or multiples of the second voltage through the fifth switching circuit during the pushing phase; and
a sixth switching circuit, coupled to the voltage adjustment unit, the voltage adjustment unit receiving the voltage of the capacitor through the sixth switching circuit during the pushing phase.

7. The voltage control circuit of claim 1, further comprising:
a storage capacitor, receiving multiples of the first voltage or multiples of the second voltage from the capacitor during the pushing phase.

8. The voltage control circuit of claim 1, wherein the first voltage is a positive voltage and the second voltage is a negative voltage.

9. The voltage control circuit of claim 1, wherein the voltage control circuit is used to drive a display panel.

10. A voltage generation device, comprising:
a first voltage generating circuit, providing a first voltage;
a second voltage generating circuit, providing a second voltage;
a capacitor, receiving the first voltage and the second voltage during a charging phase; and
a voltage control circuit, adjusting the voltage of the capacitor during a pushing phase, wherein the voltage control circuit generates multiples of the first voltage or multiples of the second voltage through the capacitor during the pushing phase.

11. The voltage generation device of claim 10, wherein the capacitor is disposed outside the voltage control circuit.

12. The voltage generation device of claim 10, further comprising a storage capacitor, coupled to the voltage control circuit, the voltage control circuit generates multiples of the first voltage or multiples of the second voltage to the storage capacitor through the capacitor during the pushing phase.

13. The voltage generation device of claim 10, wherein the voltage control circuit comprises a voltage adjustment unit, the voltage adjustment unit receives a portion of the voltage of the capacitor and a reference voltage during the pushing phase, when the portion of the voltage of the capacitor is different from the reference voltage, the voltage adjustment unit adjusts the voltage of the capacitor.

14. The voltage generation device of claim 10, wherein the first voltage is a positive voltage, and the second voltage is a negative voltage.

15. The voltage generation device of claim 10, wherein the voltage generation device is used to drive a display panel.
